(19) United States
(12) Patent Application Publication
(10) Pub. No.: US 2026/0282309 A1
(43) Pub. Date: Sep. 17, 2026

(54) BULK FEEDER

(71) Applicant: FUJI CORPORATION, Chiryu (JP)

(72) Inventors: Keisuke YOKOO, Nagoya-shi (JP); Yusuke YAMAZAKI, Chiryu-shi (JP); Isao KUSAKARI, Chiryu-shi (JP)

(73) Assignee: FUJI CORPORATION, Chiryu (JP)

(21) Appl. No.: 19/479,930

(22) PCT Filed: Jun. 2, 2023
(86) PCT No.: PCT/JP2023/020711

§ 371 Date: Oct. 29, 2025

(51) Int. Cl. H05K 13/08; H05K 13/02; H05K 13/04

(52) U.S. Cl. CPC H05K 13/0895; H05K 13/028; H05K 13/043

(57) ABSTRACT

There is provided a bulk feeder including: a feeder main body, a track member detachably attached to the feeder main body and having a supply region which opens upward for supplying a component to be collectable; a shutter provided to be openable and closable on the track member and configured to close an opening of the supply region in a closed state; a movable member provided on the feeder main body to be movable in an opening and closing direction of the shutter; and a coupling section configured to couple the shutter and the movable member by attraction of a pair of magnets respectively provided at facing positions of the shutter and the movable member when the track member is positioned at a predetermined attachment position at the feeder main body.

### TECHNICAL FIELD

The present disclosure relates to a bulk feeder.

### BACKGROUND ART

A bulk feeder is installed on a component mounter that mounts components on a board, and is used to supply components in a bulk state in a supply region. When the type of component supplied by the bulk feeder is changed, maintenance, such as removing the components remaining in the feeder, is performed as appropriate in addition to replacing a component case. There is a type of bulk feeder in which a track member in which a supply region and a component conveyance path are formed is configured to be detachable from a feeder main body to improve maintainability. Further, the track member is provided with a shutter capable of closing the supply region to prevent scattering of the components and mixing of foreign matter.

### CITATION LIST

### Patent Literature

Patent Literature 1: WO 2021/095219

### BRIEF SUMMARY

### Technical Problem

In a case where the shutter described above is provided to be openable and closable with respect to the track member and constitutes a detachable unit together with the track member, when the unit is attached to the feeder main body, it is necessary to position the track member and the shutter at respective attachment positions. At this time, if there is an error in the positioning of the shutter, it may cause a malfunction in the operation. Further, the necessity of positioning of the two members in the attachment of the unit may cause deterioration in efficiency.

An object of the present description is to provide a bulk feeder capable of improving maintainability and improving efficiency of attachment and detachment in a type in which a unit having a component conveyance path is detachable.

### Solution to Problem

According to the present description, there is disclosed a bulk feeder including: a feeder main body; a track member detachably attached to the feeder main body and having a supply region which opens upward for supplying a component to be collectable; a shutter provided to be openable and closable on the track member and configured to close an opening of the supply region in a closed state; a movable member provided on the feeder main body to be movable in an opening and closing direction of the shutter; and a coupling section configured to couple the shutter and the movable member by attraction of a pair of magnets respectively provided at facing positions of the shutter and the movable member when the track member is positioned at a predetermined attachment position at the feeder main body.

### Advantageous Effects

With such a configuration, since the unit including the track member and the shutter is detachable from the feeder main body, maintainability can be improved. Further, since the coupling section couples the shutter and the movable member by a magnetic force of the pair of magnets, positioning of the shutter in the attachment can be omitted, and efficiency of attachment and detachment of the unit including the track member and the shutter can be improved.

### BRIEF DESCRIPTION OF DRAWINGS

FIG. 1 is a plan view schematically illustrating a component mounter installed with a bulk feeder.

FIG. 2 is a perspective view illustrating an appearance of the bulk feeder.

FIG. 3 is a side view schematically illustrating a main section of the bulk feeder, a conveyance unit detached from a feeder main body, and a component case.

FIG. 4 is a plan view as viewed from the IV direction in FIG. 3.

FIG. 5 is a perspective view illustrating the feeder main body and a detached track unit.

FIG. 6A is a plan view illustrating a first aspect of a coupling section.

FIG. 6B is a plan view illustrating a second aspect of the coupling section.

FIG. 6C is a plan view illustrating a third aspect of the coupling section.

FIG. 7 is a perspective view illustrating an opening and closing operation of a shutter.

### DESCRIPTION OF EMBODIMENTS

Bulk feeder 20 will be described with reference to the drawings. Bulk feeder 20 is installed in, for example, component mounter 10 for mounting components on a board. Bulk feeder 20 supplies components in a bulk state that is not packaged in a carrier tape, a stick, or the like

### 1. Configuration of Component Mounter 10

Component mounter 10 constitutes a production line for producing board products together with multiple types of board work machines including, for example, another component mounter 10. The board work machines constituting the production line described above can include a printer, an inspection device, a reflow oven, and the like.

### 1-1. Board Conveyance Device 11

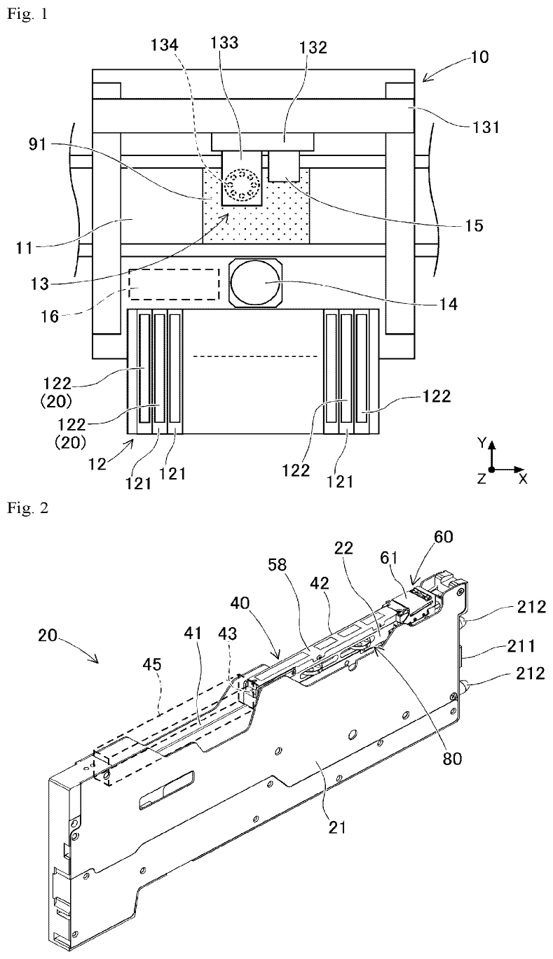

As illustrated in FIG. 1, component mounter 10 includes board conveyance device 11. Board conveyance device 11 consecutively conveys board 91 in a conveyance direction and positions board 91 at a predetermined position within component mounter 10.

### 1-2. Component Supply Device 12

Component mounter 10 includes component supply device 12. Component supply device 12 supplies components to be mounted on board 91. Component supply device 12 includes feeders 122 which are installed respectively in multiple slots 121. A tape feeder that supplies components to be collectable, for example, by feeding and moving a carrier tape accommodating a large number of components is applied as feeder 122. In addition, bulk feeder 20 which supplies components accommodated in a bulk state to be collectable is applied as feeder 122. Details of bulk feeder 20 will be described below.

### 1-3. Component Transfer Device 13

Component mounter 10 includes component transfer device 13. Component transfer device 13 transfers a component supplied by component supply device 12 to a predetermined mounting position on board 91. Component transfer device 13 includes head drive device 131, moving section 132, mounting head 133, and suction nozzle 134. Head drive device 131 moves moving section 132 in a horizontal direction (X direction and Y direction) by a linear movement mechanism. Mounting head 133 is detachably fixed to moving section 132 by a clamp member (not illustrated), and is provided to be movable in the horizontal direction within the component mounter.

Mounting head 133 rotatably and liftably supports multiple suction nozzles 134. Suction nozzle 134 is a holding member that collects and holds a component supplied by feeder 122. Suction nozzle 134 picks up the component supplied by feeder 122 by using supplied negative pressure air. As a holding member to be attached to mounting head 133, a chuck or the like that holds the component by gripping the component can be adopted.

### 1-4. Part Camera 14 and Board Camera 15

Component mounter 10 includes part camera 14 and board camera 15. Part camera 14 and board camera 15 are digital imaging devices having imaging elements, such as CMOS. Part camera 14 and board camera 15 perform imaging based on a control signal and send image data acquired by the imaging. Part camera 14 is configured to be able to image a component held by suction nozzle 134 from below. Board camera 15 is provided on moving section 132 to be movable in the horizontal direction integrally with mounting head 133. Board camera 15 is configured to image board 91 from above.

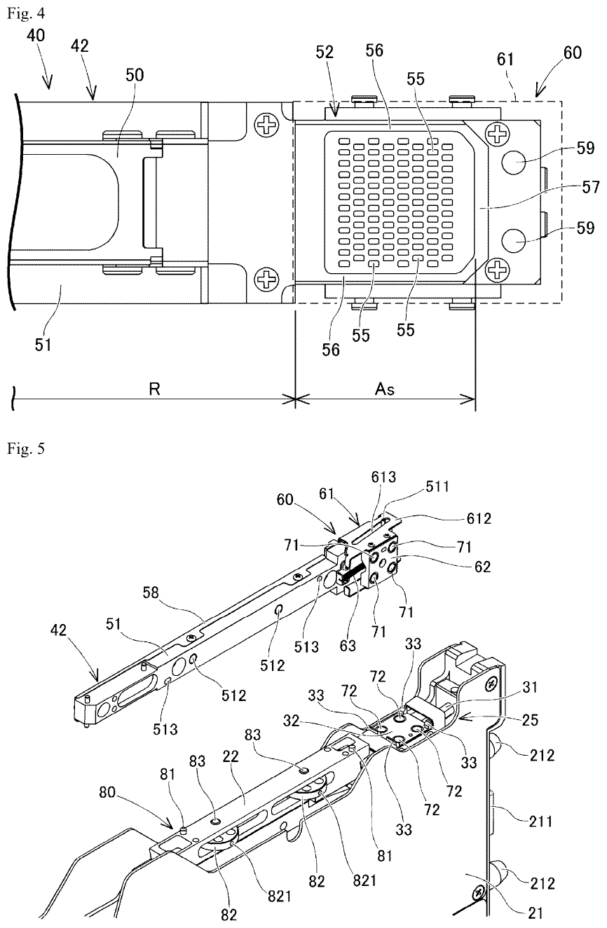

In addition, board camera 15 can use various devices or the like as an imaging target as long as the various devices are within a movable range of moving section 132, in addition to using a surface of board 91 as the imaging target. For example, in the present embodiment, as illustrated in FIG. 4, board camera 15 can image supply region As to which bulk feeder 20 supplies a component or fiducial mark 59 provided on an upper part of bulk feeder 20 within a camera field of view. In this manner, board camera 15 can be used commonly to image different imaging targets to acquire the image data used for various types of image processing.

### 1-5. Control Device 16

As illustrated in FIG. 1, component mounter 10 includes control device 16. Control device 16 is mainly configured with CPU and various types of memories, a control circuit, and a storage device. Various data including a control program used for controlling the mounting process and the like are stored in control device 16. The control program indicates the mounting position, the mounting angle, and the component type of the component mounted on board 91 in the mounting process in a scheduled mounting order.

Control device 16 executes recognition processing of a holding state of a component held by each of the multiple holding members (suction nozzles 134). Specifically, control device 16 executes image processing on image data acquired through imaging by part camera 14 and recognizes a position and an angle of each component with respect to a reference position of mounting head 133. Here, control device 16 may execute image processing on image data acquired by imaging the component, for example, from the side, below, or above with a head camera unit provided integrally with mounting head 133, in addition to part camera 14.

Control device 16 controls a mounting operation of the component by mounting head 133 based on the control program to execute the mounting process. Here, the mounting process includes a process of repeating a pick-and-place cycle (a PP cycle) which includes a collection operation and a mounting operation multiple times. The “collection operation” described above is an operation in which a component supplied by component supply device 12 is collected by suction nozzle 134. In addition, the “mounting operation” described above is an operation of mounting the collected component at a predetermined mounting angle at a predetermined mounting position on board 91.

Control device 16 controls an operation of the component supply device 12 including bulk feeder 20 when the collection operation is executed. The control for bulk feeder 20 as a target includes, for example, control of a component supply operation by bulk feeder 20. Control device 16 recognizes supply states of multiple components in supply region As of bulk feeder 20 based on the image data acquired by the imaging of the camera (in the present embodiment, board camera 15).

Recognition processing of the supply state includes a processing step of recognizing whether there is a component that is collectable in supply region As and a processing step of, if there is a component that is collectable, recognizing a position and an angle of the component. Then, control device 16 controls an operation of mounting head 133 in a collection operation based on the result of the recognition processing of the supply state. In the mounting process, control device 16 controls the operation of mounting head 133 based on information output from various sensors, the result of image processing, the control program, or the like. Thus, the positions and the angles of multiple suction nozzles 134 supported by mounting head 133 are controlled. As a result, the component held by suction nozzle 134 is mounted at a predetermined mounting position and at a predetermined mounting angle which are instructed by the control program.

### 2. Configuration of Bulk Feeder 20

Bulk feeder 20 is installed in component mounter 10 and functions as a part of the component supply device. Bulk feeder 20 supplies components accommodated in a bulk state, in which the components are not aligned as in a carrier tape (in an irregular state in which respective postures thereof are not regular). Accordingly, since bulk feeder 20 does not use a carrier tape, unlike with a tape feeder, there is an advantage in that loading of the carrier tape, collection of the used tape, and the like can be omitted.

For example, there is bulk feeder 20 of a type that supplies a component in an irregular posture to supply region As having a plane shape. However, when components are so close to be in contact with each other or accumulated (a state of being overlapped in an up-down direction) or the components are placed horizontally with width directions aligned in the up-down direction in supply region As, component mounter 10 cannot regard the components as collection targets. Therefore, in order to increase a ratio of collectable components, there is bulk feeder 20 of a type that supplies components to supply region As in an aligned state. In the present embodiment, bulk feeder 20 of a type in which components are aligned will be described as an example.

### 2-1. Feeder Main Body 21 and Support Member 22

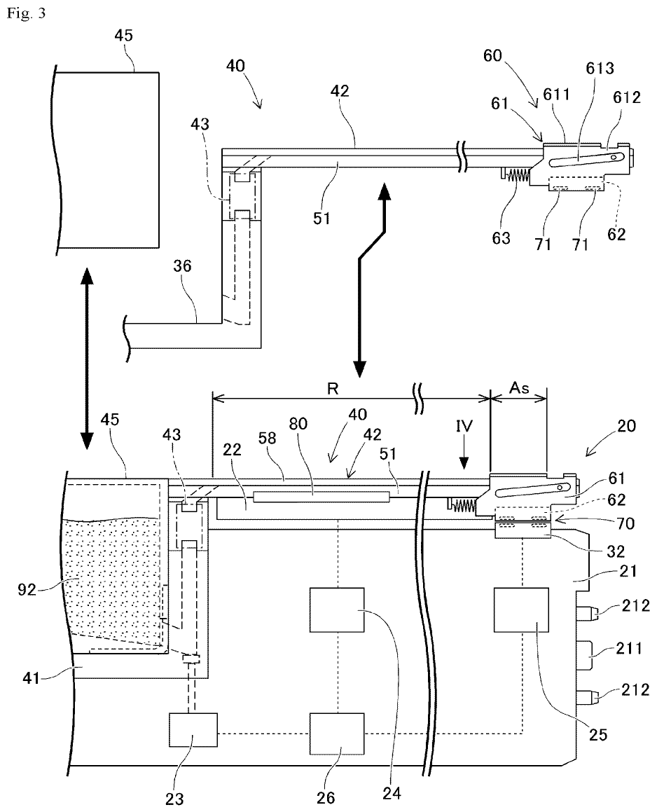

As illustrated in FIG. 2 and FIG. 3, bulk feeder 20 includes feeder main body 21. Feeder main body 21 is formed in a flat box shape. Connector 211 and two pins 212 are provided on a front portion (the right side end portion in FIG. 3) of feeder main body 21. When feeder main body 21 is installed in slot 121 of component supply device 12, power is supplied via connector 211, and feeder main body 21 is communicable with control device 16 of component mounter 10. Two pins 212 are inserted into guide holes provided in slot 121 to thereby be used to position feeder main body 21 when feeder main body 21 is installed in slot 121.

As illustrated in FIG. 3, bulk feeder 20 includes support member 22. Support member 22 is provided to be capable of vibrating with respect to feeder main body 21. Support member 22 is formed in a block shape extending in the front-rear direction of feeder main body 21, and supports track member 51 attached to an upper surface. Predetermined vibration is applied to support member 22 by vibration device 24 to be described below. In the present embodiment, track member 51 supported by support member 22 is fixed by lock member 80. A screw type or a chuck type is applied to lock member 80. A detailed configuration of lock member 80 will be described below.

### 2-2. Conveyance Unit 40

As illustrated in FIG. 2 and FIG. 3, bulk feeder 20 includes conveyance unit 40. Conveyance unit 40 is detachably attached to feeder main body 21. Conveyance unit 40 supports set component case 45. Conveyance unit 40 is a unit for conveying a component from a region for receiving the component discharged from component case 45 to supply region As.

After bulk feeder 20 is used for a predetermined mounting process, removal work to remove all components inside the feeder in preparation for next use is performed as a type of maintenance. Conveyance unit 40 is configured to be detachable from feeder main body 21 as a unit that functions as a flow path for components to improve efficiency, assuming the removal work described above. In the present embodiment, conveyance unit 40 includes case holder 41, track unit 42, and coupling member 43.

Component case 45 is an external device that accommodates multiple components in a bulk state. Component case 45 is replaceably set in case holder 41 in conveyance unit 40 of bulk feeder 20. Component case 45 is formed in a flat box shape as a whole similarly to feeder main body 21. Component case 45 is set in case holder 41, and a component can be discharged from a discharge port formed in a lower portion.

### 2-2-1. Case Holder 41

Case holder 41 is provided to be capable of vibrating with respect to feeder main body 21. Case holder 41 is vibrated by a vibration device (not illustrated). Case holder 41 supports set component case 45. Case holder 41 receives a component discharged from component case 45. In the present embodiment, a portion of case holder 41 that receives the component has an inclined surface inclined forward with respect to a horizontal surface. Case holder 41 is formed with a flow path for components that extends upward from a lower end portion of the inclined surface described above.

### 2-2-2. Track Unit 42

Track unit 42 includes a track member detachably attached to feeder main body 21. Track member 51 is attached to feeder main body 21 via support member 22. Thus, vibration is applied to track member 51 by vibration device 24 via support member 22. Track member 51 is formed with conveyance path R through which multiple components are conveyed, and supply region As that communicates with conveyance path R and opens upward such that the multiple components can be collected. Here, “supply region As” is a region to which the component is supplied in a bulk state, and is a region from which the components can be collected by component mounter 10. Further, “conveyance path R” is a component passage through which the components flowing from case holder 41 side to track member 51 are conveyed to supply region As.

Track member 51 is formed to extend in a front-rear direction (the right-left direction in FIG. 3) of feeder main body 21 as an overall shape. In the present embodiment, as illustrated in FIG. 4, alignment member 52 is replaceably attached to track member 51. Alignment member 52 is, for example, one or multiple plate-shaped members. In this manner, track unit 42 is unitized by attaching one selected from multiple types of alignment members 52 corresponding to shapes of multiple types of components to common track member 51.

As illustrated in FIG. 4, alignment member 52 forms multiple cavities 55 arranged in a predetermined pattern (in a zigzag pattern in the present embodiment). Each of multiple cavities 55 has a rectangular shape slightly larger than an outer shape of a component supplied by bulk feeder 20. In this manner, bulk feeder 20 includes multiple cavities 55, in which the component is accommodated in a posture in which a thickness direction of the component is the up-down direction, in supply region As to which the component is supplied such that the component can be collected.

Pair of side walls 56, which protrudes upward, are formed at both edges of track unit 42 in a width direction (an up-down direction in FIG. 4). Pair of side walls 56 surround a peripheral edge of conveyance path R together with tip portion 57 of track unit 42 to prevent leakage of the components conveyed through conveyance path R. Cover 58 which covers conveyance path R from above is fixed to a position above track member 51. Cover 58 is configured to prevent the components from coming out of conveyance path R. Pair of left and right circular fiducial marks 59 indicating a reference position of supply region As are affixed to an upper surface of tip portion 57.

Track unit 42 includes shutter unit 60 provided on a front end side of track member 51. Shutter unit 60 is provided to be openable and closable on track member 51, and includes shutter 61 that closes an opening of supply region As in a closed state. When track unit 42 is attached to feeder main body 21, shutter 61 is coupled to shutter drive device 25 by coupling section 70 to be described below. The opening and closing operation of shutter 61 is controlled by shutter drive device 25. By opening and closing shutter 61, bulk feeder 20 can prevent the component from protruding and foreign matter from being mixed into supply region As. Details of shutter unit 60 and coupling section 70 will be described below.

### 2-2-3. Coupling Member

Coupling member 43 couples case holder 41 and track unit 42 such that multiple components can flow therebetween. Coupling member 43 has a tubular shape in which the multiple components can flow inside. Coupling member 43 has flexibility and absorbs each vibration by being deformed according to the vibration of case holder 41 and the vibration of track unit 42. Thus, coupling member 43 reduces or blocks vibration transmitted between case holder 41 and track unit 42 that vibrate independently of each other.

### 2-3. Air Supply Device 23 and Vibration Device 24

Bulk feeder 20 includes air supply device 23 that supplies positive pressure air to conveyance unit 40. When attached to feeder main body 21, conveyance unit 40 is supplied with positive pressure air by air supply device 23, and causes the multiple components to flow from case holder 41 to track unit 42 via coupling member 43. In the present embodiment, air supply device 23 supplies the positive pressure air, which is supplied from an outside, from below case holder 41, based on a command from feeder control device 26 to be described below.

Bulk feeder 20 includes vibration device 24 provided in feeder main body 21. Vibration device 24 applies vibration to track member 51 such that the multiple components are conveyed between conveyance path R communicating with supply region As and supply region As. In the present embodiment, vibration device 24 applies vibration to track member 51 via support member 22. When vibration device 24 applies vibration to track member 51, track member 51 performs an elliptical motion in a side view.

Thus, a forward and upward external force or a backward and upward external force is applied to multiple components at conveyance path R in accordance with a rotational direction of the elliptical motion of track member 51. As a result, multiple components are conveyed to a front side or a rear side of track member 51. Bulk feeder 20 can vary the conveyance speed of components to be conveyed, the degree of dispersion of components, the conveyance direction, and the like by controlling the frequency and amplitude of the vibration applied to track member 51, and the rotational direction of the elliptical motion caused by the vibration.

### 2-4. Shutter Drive Device 25

Shutter drive device 25 is a drive device that opens and closes shutter 61 of shutter unit 60 in a state in which conveyance unit 40 is attached to feeder main body 21. Shutter drive device 25 switches shutter 61 between a closed state and an opened state, based on a command from feeder control device 26. The closed state of shutter 61 is a state in which shutter 61 comes into contact with track member 51 and the opening of supply region As is completely closed.

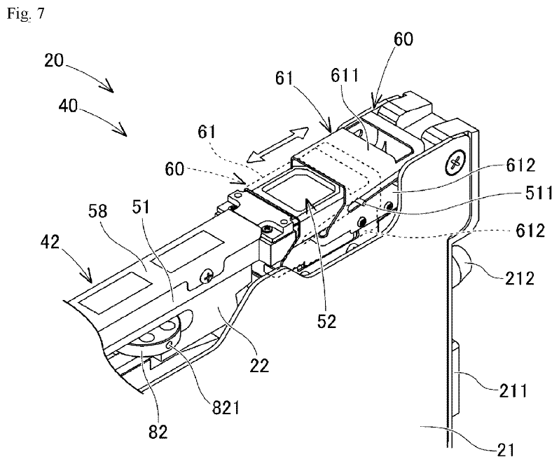

The opened state of shutter 61 is a state in which the opening of supply region As is not closed and a principal range of supply region As (range in which multiple cavities 55 are provided in the present embodiment) is exposed (see FIG. 7). At this time, suction nozzle 134 can execute a collection operation for components in any of cavities 55. The state of shutter 61 includes an intermediate state between the closed state and the opened state. The intermediate state of shutter 61 is a state in which shutter 61 is slightly separated from track member 51 (separated to such an extent that vibration of the track member is not hindered and components do not leak from a gap).

### 2-5. Feeder Control Device 26

Bulk feeder 20 includes feeder control device 26. Feeder control device 26 is mainly configured with CPU, various memories, and a control circuit. Feeder control device 26 is supplied with power via connector 211, in a state in which bulk feeder 20 is installed in a slot of component mounter 10, and is in a communicable state with the control device of component mounter 10.

Feeder control device 26 controls operations of air supply device 23, vibration device 24, shutter drive device 25, and the like. For example, feeder control device 26 controls the operation of vibration device 24 based on a parameter set in advance such that the component supply process is executed. Thus, vibration is applied to track member 51, and the components on conveyance path R are conveyed by receiving the external force to move in the conveyance direction. Feeder control device 26 causes the operation of shutter drive device 25 to switch shutter 61 to a predetermined state.

### 3. Component Supply Process of Bulk Feeder 20

A component supply process by bulk feeder 20 configured as described above will be described. First, feeder control device 26 discharges components from component case 45 based on, for example, a supply command from the outside. Specifically, feeder control device 26 controls the operation of the vibration device such that vibration is applied to case holder 41 to which component case 45 is attached. When component case 45 vibrates, the components are discharged from a discharge port. The discharged components drop to an inclined portion of case holder 41 positioned below the discharge port and slide and move forward along the inclined surface of the inclined portion. Thus, the components stay at the lower end portion in front of the inclined portion.

In this state, feeder control device 26 commands air supply device 23 to supply positive pressure air. The positive pressure air supplied from air supply device 23 blows up the multiple waiting components, and flows through the flow path formed in case holder 41 together with the components. Thus, the positive pressure air and the multiple components flow from case holder 41 to track unit 42 via coupling member 43, and reach conveyance path R of track unit 42. Here, the positive pressure air is exhausted to the outside from an exhaust port formed in cover 58 of track unit 42.

Thereafter, when vibration device 24 for conveying the component applies vibration to track member 51, the multiple components are conveyed to the supply region As side. In addition, vibration for moving the components forward or backward is applied to track member 51 in accordance with the supply amount of components in supply region As, or the like. Some of the multiple components conveyed to supply region As are accommodated in cavities 55. The components that are not accommodated in cavities 55 are further moved backward to conveyance path R by the vibration applied by vibration device 24, and are removed from supply region As. With the component supply process, the components accommodated in multiple cavities 55 are supplied in a state in which the components can be collected by component mounter 10.

### 4. Attachment and Detachment of Track Unit 42

### 4-1. Fixing of Support Member 22 and Track Member 51 by Lock Member 80

Track member 51 of track unit 42 is fixed to support member 22 by lock member 80 as described above. Specifically, as illustrated in FIG. 5, lock member 80 includes pair of positioning pins 81 protruding upward from the upper surface of support member 22. When track member 51 is attached, pair of positioning pins 81 are inserted into pair of pin holes 513 provided on a lower surface of track member 51 facing the upper surface of support member 22.

Lock member 80 includes two wheels 82 and two screws 83. Each of two wheels 82 is rotatably provided on support member 22. An outer diameter of each of two wheels 82 is set such that an outer peripheral portion protrudes outward from support member 22 and is smaller than a width of bulk feeder 20, in a width direction of bulk feeder 20. Thus, a worker can manually rotate wheel 82. In addition, wheel 82 is formed with locking hole 821 that locks an inserted rotating jig in a circumferential direction. The worker may insert the rotating jig into locking hole 821 to rotate wheel 82.

Two screws 83 are provided coaxially and integrally with two wheels 82. Tip portions of two screws 83 protrude upward from the upper surface of support member 22. In the attachment operation of conveyance unit 40, first, track member 51 is positioned by pair of positioning pins 81 and is supported by support member 22. Next, when two wheels 82 are rotated, each of screws 83 is inserted into and fastened to screw hole 512 provided on the lower surface of track member 51. In this manner, lock member 80 adopts a screw type that fixes track member 51 supported by support member 22. In detachment work of conveyance unit 40, the work is performed in a reverse order.

### 4-2. Detailed Configuration of Shutter Unit 60 and Opening and Closing Operation of Shutter 61

Shutter unit 60 includes shutter 61, bracket 62, and spring 63. Shutter 61 is formed in a U-shape that opens downward when viewed in the front-rear direction as a whole. In the present embodiment, as illustrated in FIG. 3 and FIG. 5, shutter 61 has upper wall portion 611 and pair of side wall portions 612. Upper wall portion 611 is in contact with track member 51 in the closed state to close the opening of supply region As, and is separated from track member 51 in the intermediate state.

Pair of side wall portions 612 are positioned outside track member 51 in the right-left direction and extend downward from both end edges of upper wall portion 611, thereby restricting the protrusion of component 92 from the opening of supply region As together with upper wall portion 611 in the intermediate state. Long hole 613 inclined with respect to the front-rear direction is formed at each of pair of side wall portions 612. Guide pin 511 protruding in a width direction from a side surface of track member 51 penetrates long hole 613. Thus, shutter 61 is supported by track member 51 to move along guide pin 511.

Bracket 62 is a block-shaped member fixed to couple lower end portions of pair of side wall portions 612 to each other. Bracket 62 moves integrally with shutter 61 when an opening and closing operation of shutter 61 is performed. Spring 63 is an elastic member coupling track member 51 and bracket 62. Spring 63 is a coil-shaped extension spring.

Spring 63 exerts an elastic force to always bias bracket 62 backward. Since shutter 61 is supported by guide pin 511 via long hole 613 inclined with respect to the horizontal front-rear direction, shutter 61 is maintained in a closed state (a state of being positioned at the rear end of the movable range and biased downward by track member 51) by the elastic force of spring 63.

As illustrated in FIG. 5, shutter drive device 25 includes rail 31, slider 32, and multiple guides 33. Rail 31 extends in the front-rear direction and the up-down direction of feeder main body 21. Rail 31 is formed in a straight line extending gradually upward from the rear side toward the front side. The extending direction of rail 31 corresponds to the opening and closing direction of shutter 61.

Slider 32 is a movable member provided to be movable in the extending direction of rail 31. Slider 32 is coupled to shutter 61 via bracket 62 by coupling section 70. When slider 32 moves in the front-rear direction along rail 31, shutter 61 moves in the front-rear direction integrally with slider 32 and bracket 62. At this time, shutter 61 moves in the up-down direction in accordance with a movement amount in the front-rear direction by the inclination of rail 31.

Multiple guides 33 are provided at four corners of slider 32 having a rectangular shape in a top view, and protrude upward from the upper surface of slider 32. Guide 33 guides bracket 62 of shutter unit 60 to a predetermined position in the front-rear direction when track unit 42 is attached to feeder main body 21. Further, guide 33 restricts the movement of bracket 62 in the front-rear direction with respect to slider 32 after shutter unit 60 is coupled to slider 32.

As shutter drive device 25, various forms can be adopted as a mechanism that moves slider 32. For example, shutter drive device 25 may adopt a configuration in which an arm rotatably provided on feeder main body 21 is rotated by a motor and slider 32 is moved according to the rotation amount of the arm. When shutter drive device 25 moves slider 32 forward, bracket 62 coupled to slider 32 moves forward against the biasing force of spring 63.

Thus, shutter 61 fixed to bracket 62 is moved forward to be in the opened state as illustrated in FIG. 7. At this time, shutter 61 moves upward by the inclination amount of rail 31. In addition, shutter 61 is in the opened state, supply region As in which multiple cavities 55 are arranged is exposed, and the component collection operation using suction nozzle 134 can be performed from above.

Further, shutter drive device 25 can bring shutter 61 into the intermediate state by supplying predetermined power to the motor and rotating the arm by a certain angle from an initial angle. When the power to the motor of shutter drive device 25 is cut off, shutter 61 is moved to an initial position on the rear side together with bracket 62 by the biasing force of spring 63, as indicated by the broken line in FIG. 7, and is in the closed state.

### 4-3. Coupling Between Shutter Drive Device 25 and Shutter 61 by Coupling Section 70

In the present embodiment, shutter 61 is provided to be openable and closable with respect to track member 51, and constitutes detachable track unit 42, together with track member 51. When track unit 42 is attached to feeder main body 21, it is necessary to fix track member 51 to support member 22 and couple shutter 61 to shutter drive device 25. It is assumed that a screw type or the like is adopted for coupling shutter 61 and shutter drive device 25.

However, when track unit 42 is attached, positioning of the two members (track member 51 and shutter 61) increases a work load and reduces efficiency. Further, when fixed in a state in which there is an error in positioning, it may cause a malfunction in the opening and closing operation of shutter 61. Therefore, in bulk feeder 20 of a type in which track unit 42 is detachable from feeder main body 21, the present embodiment adopts a configuration capable of improving maintainability and efficiency of attachment and detachment.

Specifically, as illustrated in FIG. 3, bulk feeder 20 includes coupling section 70 provided with pair of magnets 71 and 72 that attract each other on the shutter 61 side and the slider 32 side that is a movable member. Pair of magnets 71 and 72 are provided at respective positions facing shutter 61 and slider 32 which is a movable member when track member 51 is positioned at a predetermined attachment position in feeder main body 21. In the present embodiment, magnet 71 on the shutter 61 side is embedded in bracket 62 fixed to shutter 61. Magnet 72 on the slider 32 side is embedded in slider 32. Thus, when pair of magnets 71 and 72 approach each other in the attachment of track unit 42, pair of magnets 71 and 72 are attracted to each other, and shutter 61 is coupled to slider 32.

Here, the magnet can be used as a configuration for coupling shutter 61 to shutter drive device 25 as described above. However, when the magnet is provided on a first one of the shutter 61 side and the shutter drive device 25 side and a magnetic body attracted to the magnet is provided on a second one thereof, the magnetic body is magnetized and the magnetic force of the magnet or the magnetic body may reach supply region As. Then, the components conveyed to supply region As may be attracted to each other or the components may be difficult to be accommodated in cavity 55, which may affect the component supply operation.

On the other hand, it is found that the influence of the magnetic force on supply region As can be suppressed by providing pair of magnets 71 and 72 as in coupling section 70 of the present embodiment. That is, in the configuration including pair of magnets 71 and 72, the magnetic force affecting the component conveyed to supply region As is reduced, and the occurrence of a phenomenon in which the components are attracted to each other or the component is difficult to be accommodated in cavity 55 is prevented. The number of pairs or the arrangement of magnets 71 and 72 may be changed to improve the coupling force and efficiency of coupling section 70 as described below.

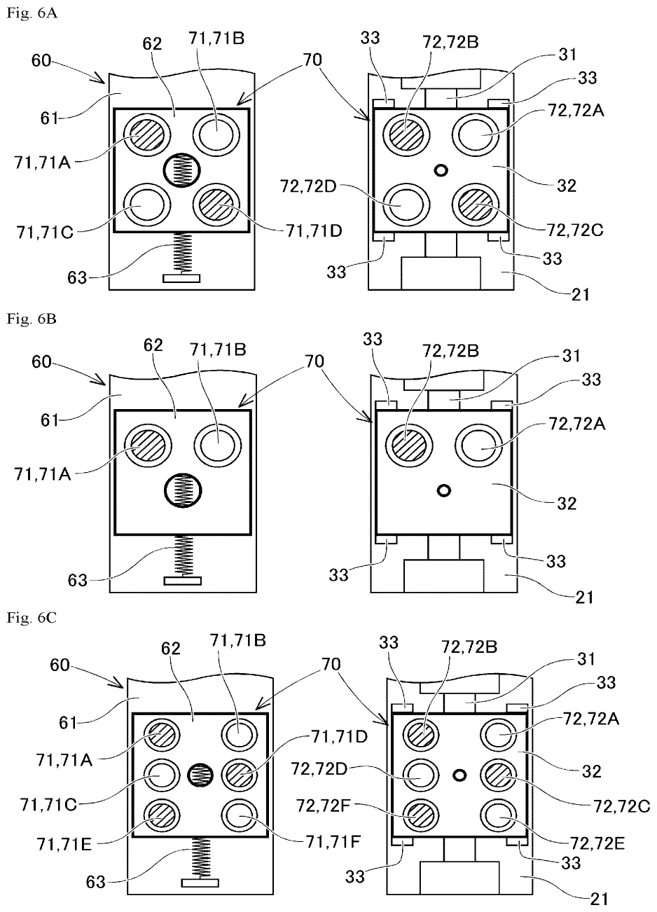

In a first aspect, as illustrated in FIG. 6A, coupling section 70 includes multiple pairs of magnets 71 and 72. Here, pair of adjacent magnets 71 and 72 are set such that magnetic poles of magnets 71 provided in shutter 61 are opposite to each other. In other words, pair of adjacent magnets 71 and 72 are set such that magnetic poles of magnets 72 provided in slider 32 are opposite to each other. In FIG. 6A, among the magnetic poles of magnets 71 and 72, an S pole is indicated by hatching, and an N pole is indicated without hatching (the same is applied to FIGS. 6B and 6C).

A left side of FIG. 6A is a part of shutter unit 60 viewed from below, and mainly illustrates a lower surface of bracket 62 provided on shutter 61. A right side of FIG. 6A is a part of shutter drive device 25 viewed from above, and mainly illustrates an upper surface of slider 32. Coupling section 70 of the first aspect includes multiple pairs of magnets 71 and 72 arranged in a matrix in a width direction (right-left direction in FIG. 6A) of track member 51 and the component conveyance direction (up-down direction in FIG. 6A).

Coupling section 70 of the first aspect includes four pairs of magnets 71 and 72 arranged in a matrix of two rows and two columns. Specifically, among four pairs of magnets 71A to 71D and 72A to 72D, four magnets 71A to 71D provided on bracket 62 are arranged to be attracted to four magnets 72A to 72D provided at positions facing slider 32.

In a second aspect, as illustrated in FIG. 6B, coupling section 70 includes two pairs of magnets 71A to 71B and 72A to 72B arranged side by side in the width direction (right-left direction in FIG. 6B) of track member 51. In the same manner as the first aspect, in coupling section 70 of the second aspect, magnetic poles of magnets 71A and 71B on the adjacent shutter 61 side are set to be opposite to each other. In other words, magnetic poles of magnets 72A and 72B on the adjacent slider 32 side are set to be opposite to each other.

In a third aspect, as illustrated in FIG. 6C, coupling section 70 includes six pairs of magnets 71A to 71F and 72A to 72F arranged in a matrix of three rows and two columns. In the same manner as the first aspect, in coupling section 70 of the third aspect, magnetic poles of magnets 71B and 71C adjacent to magnet 71A are set to be opposite to each other. That is, magnets 71A, 71C, and 71E and magnets 71B, 71D, and 71F arranged side by side in the front-rear direction (the up-down direction in FIG. 6C) are arranged such that the magnetic poles are alternately arranged. As illustrated on a right side of FIG. 6C, the same is applied to six magnets 72A to 72F on slider 32 side.

Here, in the configuration including multiple pairs of magnets 71 and 72, it is assumed that multiple pairs of magnets 71 and 72 are arranged such that the magnetic poles of the adjacent magnets are the same, for example, the magnetic poles of all magnets 71 on shutter 61 side are N poles with respect to the opposing side, and the magnetic poles of all magnets 72 on slider 32 side are S poles with respect to the opposing side. However, as compared with the case where pair of magnets 71 and 72 are arranged in this manner, it is observed that the influence of the magnetic force on supply region As can be reduced in a case where magnets 71 and 72 are alternately arranged such that the magnetic poles of the adjacent magnets 71 (72) are opposite to each other.

In addition, in a case where an odd number of pairs of magnets 71 and 72 are arranged, if the magnetic poles of any of the adjacent magnets 71 (72) are the same and are not sufficiently separated from each other, it is considered that the magnetic force affects supply region As. From such a viewpoint, as in the above aspects, it is preferable that multiple pairs of magnets 71 and 72 are arranged in a matrix and are alternately arranged such that the magnetic poles of the adjacent magnets 71 (72) are opposite to each other.

### 5. Advantageous Effects by Configuration of Embodiment

With the configuration of the embodiment, since track unit 42 including track member 51 and shutter 61 is detachable from feeder main body 21, maintainability can be improved. Further, since coupling section 70 couples shutter 61 and slider 32, which is a movable member, by the magnetic force of pair of magnets 71 and 72, positioning of shutter 61 in the attachment can be omitted, and the efficiency of attachment and detachment of the unit including track member 51 and shutter 61 can be improved.

### 6. Modification Aspect of Embodiment

In an embodiment, track member 51 of bulk feeder 20 includes alignment member 52 having multiple cavities 55 formed therein. Meanwhile, a configuration may be adopted in which alignment member 52 is omitted. That is, in supply region As of track member 51, a recessed portion in which a component is dispersed at a position lower than the upper surface of conveyance path R, or a planar portion uniform with the upper surface of conveyance path R may be formed, so that the components are supplied in the bulk state. It should be noted that, from the viewpoint of improving the efficiency of the component supply process or reducing the load of the image processing in the recognition processing of the supply state in supply region As, the configuration described in the embodiment is preferable.

In the embodiment, bulk feeder 20 supplies the components to be mounted on board 91 by component mounter 10. Meanwhile, the components are used in a board work machine which performs predetermined work on board 91 as in component mounter 10, and various types of components can be applied as long as the articles can be supplied in a state of being accommodated in cavities 55 in bulk feeder 20. For example, bulk feeder 20 may supply a solder ball formed in a spherical shape as an example of the component. Even in such an aspect, effects similar to those of the embodiment are obtained.

### REFERENCE SIGNS LIST

10: component mounter, 20: bulk feeder, 21: feeder main body, 22: support member, 23: air supply device, 24: vibration device, 25: shutter drive device, 31: rail, 32: slider (movable member), 33: guide, 26: feeder control device, 40: conveyance unit, 41: case holder, 42: track unit, 51: track member, 52: alignment member, 55: cavity, 60: shutter unit, 61: shutter, 62: bracket, 63: spring, 43: coupling member, 45: component case, 70: coupling section, 71, 71A to 71F: magnet (of pair of magnets on shutter side), 72, 72A to 72F: magnet (of pair of magnets on movable member side), 80: lock member, As: supply region, R: conveyance path

1. A bulk feeder comprising:
a feeder main body;
a track member detachably attached to the feeder main body and having a supply region which opens upward for supplying a component to be collectable;
a shutter provided to be openable and closable on the track member and configured to close an opening of the supply region in a closed state;
a movable member provided on the feeder main body to be movable in an opening and closing direction of the shutter; and
a coupling section configured to couple the shutter and the movable member by attraction of a pair of magnets respectively provided at facing positions of the shutter and the movable member when the track member is positioned at a predetermined attachment position at the feeder main body.

2. The bulk feeder according to claim 1,
wherein the coupling section includes multiple pairs of magnets, and
a pair of adjacent magnets are set such that magnetic poles of the magnets provided in the shutter are opposite to each other.

3. The bulk feeder according to claim 2, wherein the coupling section includes two pairs of magnets arranged side by side in a width direction of the track member.

4. The bulk feeder according to claim 2, wherein the coupling section includes multiple pairs of magnets arranged in a matrix in a width direction of the track member and a conveyance direction of the component.

5. The bulk feeder according to claim 4, wherein the coupling section includes four pairs of the magnets arranged in a matrix.

6. The bulk feeder according to claim 1, further comprising:
a support member provided to be vibratable with respect to the feeder main body,
wherein the track member is attached to the feeder main body via the support member.

7. The bulk feeder according to claim 6, further comprising:
a lock member that fixes the track member supported by the support member; and
a vibration device configured to apply vibration to the track member via the support member such that multiple components are conveyed between a conveyance path communicating with the supply region and the supply region.

8. The bulk feeder according to claim 1, further comprising:
a drive device configured to move the movable member such that the shutter coupled to the movable member by the coupling section is opened and closed.

9. The bulk feeder according to claim 1, wherein the track member has multiple cavities that accommodate the components in the supply region.
